(19) United States
(12) Patent Application Publication
(10) Pub. No.: US 2014/0097451 A1
(43) Pub. Date: Apr. 10, 2014

(54) PROXIMITY SENSOR AND CIRCUIT LAYOUT METHOD THEREOF

(71) Applicant: uPI Semiconductor Corp., Zhubei City (TW)

(72) Inventor: Ping-Yuan Lin, Zhubei City (TW)

(73) Assignee: uPI Semiconductor Corp., Zhubei City (TW)

(21) Appl. No.: 14/038,818

(22) Filed: Sep. 27, 2013

(30) Foreign Application Priority Data
Oct. 4, 2012 (TW) 101136735

(51) Int. Cl. H01L 25/00; H01L 25/16

(52) U.S. Cl. CPC H01L 25/50; H01L 25/167
USPC 257/82; 438/25

(57) ABSTRACT

A proximity sensor and a circuit layout method thereof are disclosed. The proximity sensor includes a light sensor and a light emitting unit. The light sensor includes a semiconductor substrate and a bonding pad. The semiconductor substrate has a first circuit region. At least one semiconductor device is disposed in the first circuit region. The bonding pad is disposed above the first circuit region and a gap is existed between the bonding pad and the at least one semiconductor device. The bonding pad is connected to the semiconductor substrate out of the first circuit region. The light emitting unit is disposed on the bonding pad of the light sensor.

### BACKGROUND OF THE INVENTION

1. Field of the Invention

The invention relates to a proximity sensor; in particular, to a proximity sensor and a circuit layout method thereof capable of effectively reducing the volume of the proximity sensor and preventing the cross-talk of noise.

2. Description of the Prior Art

A proximity sensor senses whether an object or obstacle in front in optical way. In practical applications, the proximity sensor can be used in a smart phone or handheld device to judge whether the user is close to answer or used in a domestic robot to judge whether a furniture or personnel is in front. Please refer to FIG. 1A. FIG. 1A illustrates a cross-sectional schematic diagram of a conventional proximity sensor.

As shown in FIG. 1A, the conventional proximity sensor 1 often includes a light emitting unit 10, a light receiving unit 12, a packaging epoxy 14, and a substrate 16. After the light L from the light emitting unit 10 is emitted out through a hole H1, once the emitted light L meets an obstacle, a part of lights will be reflected by the obstacle and transmitted to a light sensing area SA on the light receiving unit 12 through a hole H2. Then, the proximity sensor can determine whether the obstacle is in front according to the reflected light R received by the light receiving unit 12 and react accordingly.

However, the semiconductor manufacturing processes used to produce the LED of the light emitting unit 10 and the light sensor of the light receiving unit 12 respectively are totally different. The LED is produced by the III-V semiconductor manufacturing process, and the light receiving unit 12 is produced by the silicon manufacturing process. Therefore, it is hard to combine these two different manufacturing processes together. As shown in FIG. 1A, in the conventional proximity sensor 1, a light emitting unit 10 and a light receiving unit 12 are arranged side by side; therefore, the conventional proximity sensor 1 is in a strip form.

FIG. 1B illustrates that a top metal layer TM is used in the light receiving unit 12 of FIG. 1A to connect the semiconductor devices 12a, 12b in a first circuit region DL to complete circuit layout, and the light emitting unit 10 should be disposed on the region of the substrate 16 outside the light receiving unit 12; therefore, larger area will be used.

In addition, in the conventional proximity sensor 1, the light emitting unit 10 and the light receiving unit 12 are substantially at the same horizontal height. In order to prevent the cross-talk of noise, even the packaging epoxy 14 can be formed by light-blocking material, a distance d is still necessary between the light emitting unit 10 and the light receiving unit 12. However, this will also make the volume of the conventional proximity sensor 1 hard to be reduced and seriously affect its applicability in handheld electronic devices.

Therefore, the invention provides a proximity sensor and circuit layout method thereof to solve the above-mentioned problems occurred in the prior arts.

### SUMMARY OF THE INVENTION

A scope of the invention is to provide a proximity sensor. In a preferred embodiment, the proximity sensor includes a light sensor, a control circuit, and a light emitting unit. The light sensor includes a semiconductor substrate and a bonding pad. The semiconductor substrate has a first circuit region. At least one semiconductor device is disposed in the first circuit region. The bonding pad is disposed above the first circuit region and a gap is existed between the bonding pad and the at least one semiconductor device. The light emitting unit is disposed on the bonding pad. The light emitting unit is electrically connected to the control circuit through the bonding pad.

In an embodiment, the bonding pad includes a flat portion and at least one supporting portion. The light emitting unit is disposed on the flat portion. The at least one supporting portion is disposed under the flat portion and used for connecting to a region of the semiconductor substrate outside the first circuit region and supporting the flat portion. The flat portion is located above the first circuit region and the gap is existed between the flat portion and the at least one semiconductor device.

In an embodiment, the control circuit is disposed in the light sensor and used to control the operation of the light sensor and the light emitting unit.

In an embodiment, the control circuit is disposed in the light sensor, the bonding pad has a metal layer, and a pin of the light emitting unit is electrically connected to the control circuit through the metal layer.

In an embodiment, the light sensor and the light emitting unit are dies.

In an embodiment, the proximity sensor further includes an epoxy used for encapsulating the light sensor and the light emitting unit.

In an embodiment, the light sensor has a light sensing area, and the light sensing area is located outside the first circuit region and the connecting location of the substrate and the bonding pad.

In an embodiment, a light emitting surface of the light emitting unit and a light sensing area on the light sensor are located on different planes respectively.

Another scope of the invention is to provide a proximity sensor circuit layout method. In a preferred embodiment, the proximity sensor circuit layout method includes the steps of: providing a semiconductor substrate and disposing at least one semiconductor device in a first circuit region of the semiconductor substrate; disposing a bonding pad above the first circuit region and a gap being existed between the bonding pad and the at least one semiconductor device; providing a control circuit; and disposing a light emitting unit on the bonding pad, and electrically connecting the light emitting unit to the control circuit through the bonding pad.

Compared to the prior arts, in the proximity sensor and circuit layout method thereof of the invention, the connecting metal layers of the semiconductor devices in the digital (or analog) circuit region of the light sensor are appropriately distributed without the top metal layer disposed at the top. Instead, the bonding pad is disposed above the light sensor to form the gaps between the bonding pad and the semiconductor devices, and the pins of the light emitting unit can be electrically connected to the control circuit in the light sensor through the metal layer of the bonding pad; therefore, the volume of the entire proximity sensor can be effectively reduced. In order to increase the reliability of the light emitting unit connecting to the light sensor, the thickness of the metal layer of the bonding pad can be increased or a layer of Polyimide (PI) is encapsulated as a protection layer.

In addition, the light emitting surface of the light emitting unit and the light sensing area on the light sensor are located on different planes respectively, and the barrier portion is disposed between the light emitting unit and the light sensing area; therefore, the cross-talk generated by scattering the lights of the light emitting unit to the light sensing area on the light sensor can be effectively prevented, so that the proximity sensor will not malfunction due to misjudgment.

The advantage and spirit of the invention may be understood by the following detailed descriptions together with the appended drawings.

### BRIEF DESCRIPTION OF THE APPENDED DRAWINGS

FIG. 1A illustrates a cross-sectional schematic diagram of a conventional proximity sensor structure.

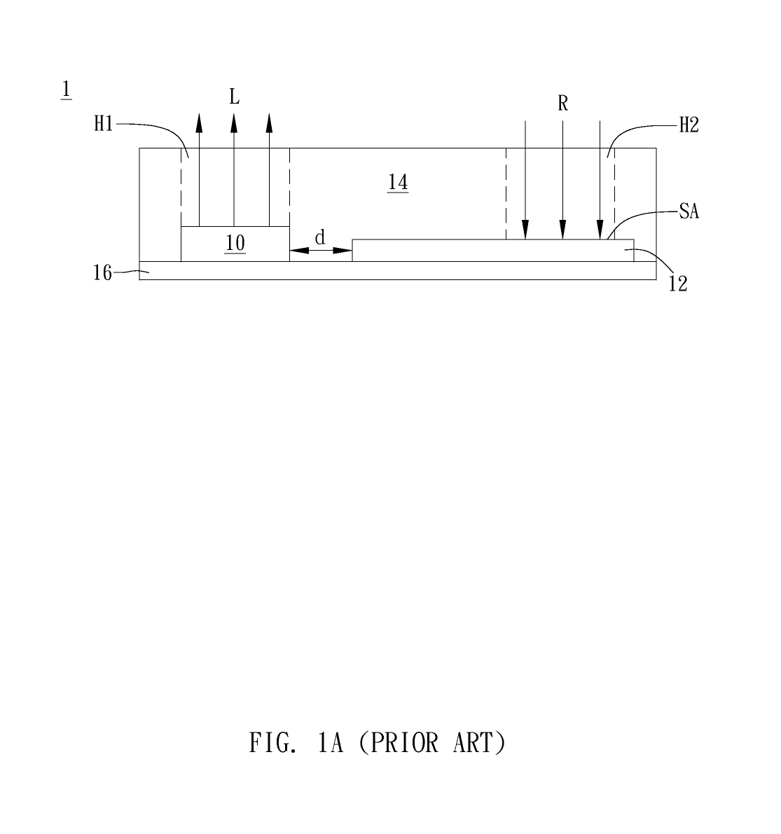

FIG. 1B illustrates that a top metal layer is used in the light receiving unit of FIG. 1A to connect the semiconductor devices in a first circuit region.

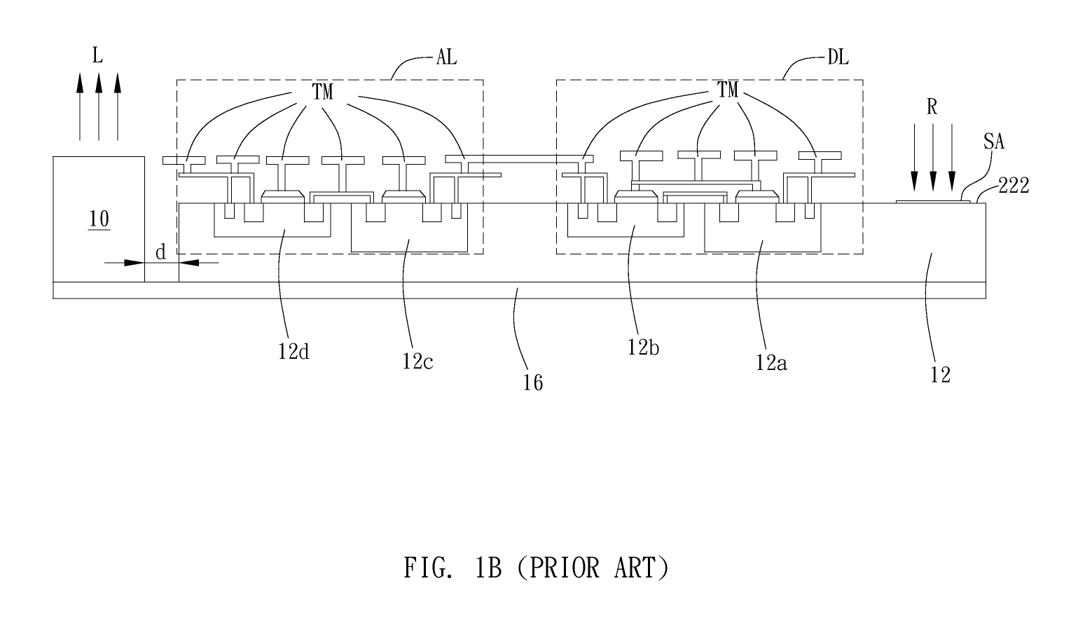

FIG. 2A illustrates a cross-sectional schematic diagram of the proximity sensor in an embodiment of the invention.

FIG. 2B illustrates a detailed cross-sectional schematic diagram of the light emitting unit of FIG. 2A disposed above the light sensor through the bonding pad.

FIG. 2C illustrates a top view of the light emitting unit (the LED die) coupling to the bonding pad disposed in the first circuit region of the light sensor.

FIG. 3 illustrates a cross-sectional schematic diagram of the proximity sensor further including a barrier portion.

FIG. 4 illustrates a flowchart of the proximity sensor circuit layout method in another embodiment of the invention.

### DETAILED DESCRIPTION OF THE INVENTION

A preferred embodiment of the invention is a proximity sensor. In practical applications, the proximity sensor can sense whether an object or an obstacle in front in optical way; therefore, it can be used in a smart phone or handheld device to judge whether the user is close to answer or used in a domestic robot to judge whether a furniture or personnel is in front. The invention can effectively reduce the volume of the entire proximity sensor and prevent the cross-talk generated by scattering the lights of the light emitting unit to the light sensing area on the light sensor at the same time.

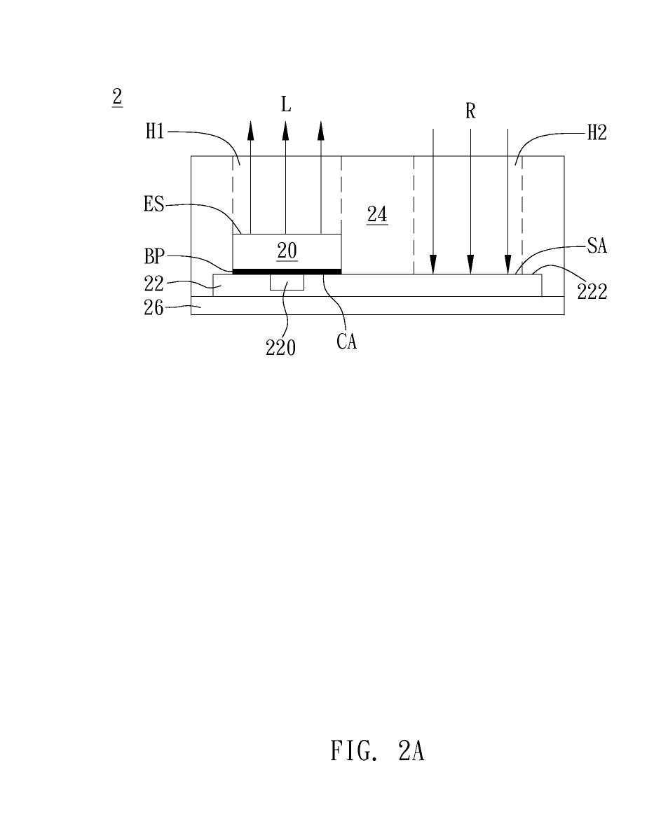

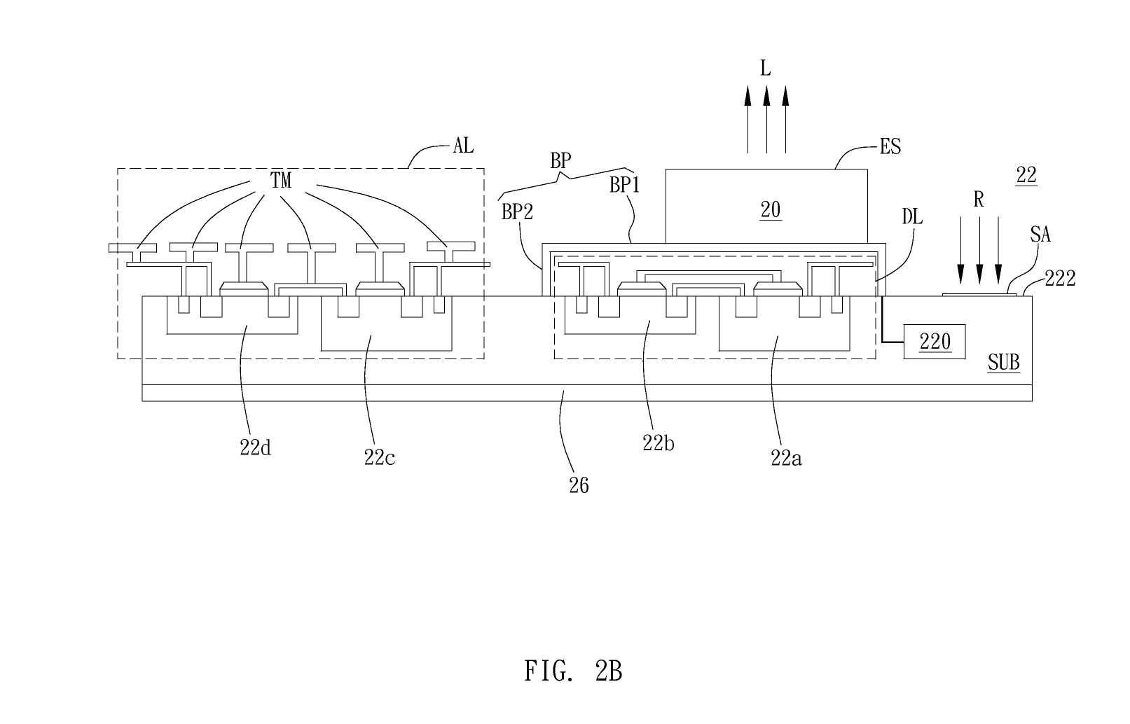

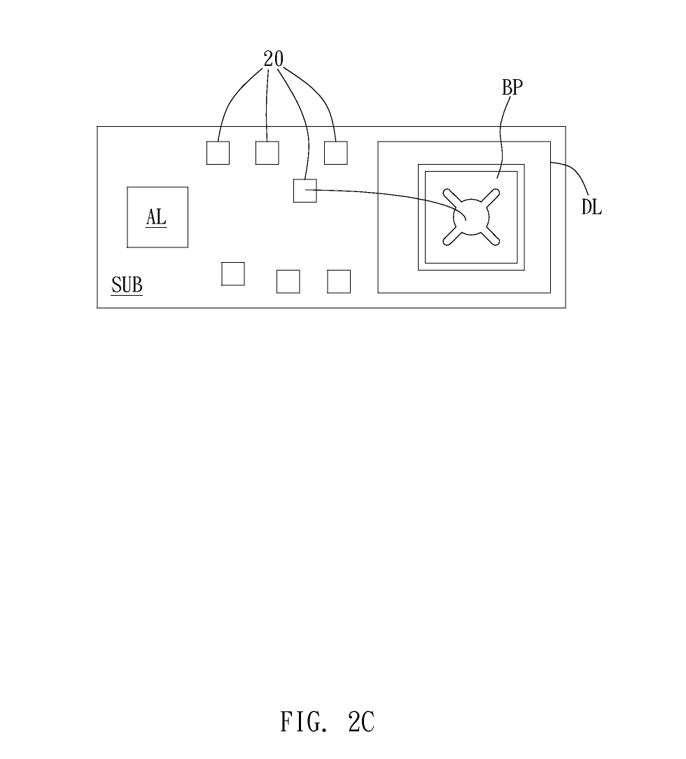

Please refer to FIG. 2A. FIG. 2A illustrates a cross-sectional schematic diagram of the proximity sensor in this embodiment. As shown in FIG. 2A, the proximity sensor 2 includes a light emitting unit 20, a light sensor 22, a molding compound 24, a substrate 26, a first hole H1, and a second hole H2. The light sensor 22 includes a control circuit 220. A first surface (the top surface) 222 of the light sensor 22 has a light sensing area SA. The light sensor 22 is disposed on the substrate 26. The light emitting unit 20 is disposed on the first surface 222 of the light emitting unit 20 and out of the light sensing area SA. In practical applications, the light emitting unit 20 can be a LED used to emit lights L, but not limited to this.

It should be noticed that the control circuit 220 is used to control the operation of the light emitting unit 20 and the light sensor 22. In fact, the control circuit 220 can be integrated with the light sensor 22 or separately disposed out of the light sensor 22, but not limited to this. In more detail, no matter the light emitting unit 20, the light sensor 22, and the control circuit 220 are three different dies or the light sensor 22 and the control circuit 220 are integrated in the same die, the control circuit 220 can control the operation of the light emitting unit 20 and the light sensor 22.

A light-blocking material can be used to encapsulate the light emitting unit 20 and the light sensor 22 to form the molding compound 24, and the first hole H1 and the second hole H2 corresponding to the light emitting unit 20 and the light sensor 22 respectively are formed on the molding compound 24, so that the light emitting unit 20 can emit the light L through the first hole H1 and the light sensor 22 can receive a reflected light R through the second hole H2.

Please also refer to FIG. 2B. FIG. 2B illustrates a detailed cross-sectional schematic diagram of the light emitting unit 20 of FIG. 2A disposed above the light sensor 22 through a bonding pad BP. As shown in FIG. 2B, the light sensor 22 includes a semiconductor substrate SUB and a bonding pad BP. In fact, the semiconductor substrate SUB can be P-type or N-type silicon substrate, but not limited to this.

The semiconductor substrate SUB has a first circuit region DL and a second circuit region AL. In this embodiment, for example, the first circuit region DL can be a digital circuit distribution region and the second circuit region AL can be an analog circuit distribution region, but not limited to this. At least one semiconductor device 22a and 22b are disposed in the first circuit region DL, and the semiconductor devices 22a and 22b in the first circuit region DL are not connected through the top metal layer TM as the prior art did. At least one semiconductor device 22c and 22d are disposed in the second circuit region AL, and the semiconductor devices 22c and 22d in the second circuit region AL are still connected through the top metal layer TM as the prior art did.

In fact, the semiconductor devices 22a˜22d can be metal-oxide-semiconductor field-effect transistor (MOSFET), but not limited to this. The first circuit region DL of the light sensor 22 can be formed by a specific circuit layout method, for example, the auto place and route (APR) method commonly used in the circuit layout region. Especially, the layout of the light sensor 22 is designed without using the top metal layer TM to route. Therefore, all APR regions can be kept to dispose the bonding pad BP.

As shown in FIG. 2B, the bonding pad BP is disposed above the first circuit region DL and a gap is existed between the semiconductors 22a and 22b in the first circuit region DL. The bonding pad BP includes a flat portion BP 1 and at least one supporting portion BP2. The light emitting unit 20 is disposed on the flat portion BP1. The at least one supporting portion BP2 is disposed under the flat portion BP1 and used for connecting to the semiconductor substrate SUB and supporting the flat portion BP1. The flat portion BP1 is located above the first circuit region DL and the gap is existed between the flat portion BP1 and the semiconductor devices 22a and 22b. In fact, the connecting position of the at least one supporting portion BP2 and the semiconductor substrate SUB can be out of the first circuit region DL, but not limited to this.

That is to say, the bonding pad BP will not contact the semiconductor devices 22a and 22b in the first circuit region DL, and the connecting position of the bonding pad BP and the semiconductor substrate SUB can be out of the first circuit region DL. Since the light emitting unit 20 is disposed on the flat portion BP1 of the bonding pad BP and the bonding pad BP has a metal layer, the pins of the light emitting unit 20 can be electrically connected to the control circuit 220 in the light sensor 22 through the flat portion BP1 and the supporting portion BP2 of the bonding pad BP. In practical applications, in order to increase the reliability of the pins of the light emitting unit 20 connecting to the light sensor 22, the thickness of the metal layer of the bonding pad BP can be increased or a layer of Polyimide (PI) can be encapsulated as a protection layer.

By doing so, the problem that the III-V semiconductor manufacturing process used to produce the light emitting unit (a LED die) and the silicon manufacturing process used to produce the light receiving unit are hard to be integrated together in the prior art can be solved. Therefore, it is unnecessary to arrange the light emitting unit 20 and the light receiving unit 22 side by side as the prior art did, instead, the light emitting unit 20 of the invention can be integrated above the light receiving unit 22 to largely reduce the volume of the proximity sensor 2. As shown in FIG. 2C, since the conventional top metal layer is not used to route in the first circuit region DL of the light sensor 22, and this space is used to dispose the bonding pad BP; therefore, the light emitting unit 20 can be electrically connected to the control circuit 220 in the light sensor 22 through the bonding pad BP.

In addition, from FIG. 2A and FIG. 2B, it can be found that the light sensing area SA on the light sensor 22 is located out of the first circuit region DL and the connection location of the semiconductor substrate SUB and the bonding pad BP. A light emitting surface ES of the light emitting unit 20 and the light sensing area SA on the light sensor 22 are located on different planes respectively, the light L emitted from the light emitting surface ES of the light emitting unit 20 is hard to be refracted to the light sensing area SA on the light sensor 22, so that the malfunction due to noise interference in prior art can be prevented.

Although the molding compound 24 of FIG. 2A is formed by the light-blocking material and the cross-talk generated by scattering the lights L of the light emitting unit 20 to the light sensing area SA on the light sensor 22 can be reduced, in order to enhance light-blocking effect to increase the accuracy of the proximity sensor, some auxiliary unit can be added in the proximity sensor structure, for example a barrier portion, a lens set, or a curved hole structure.

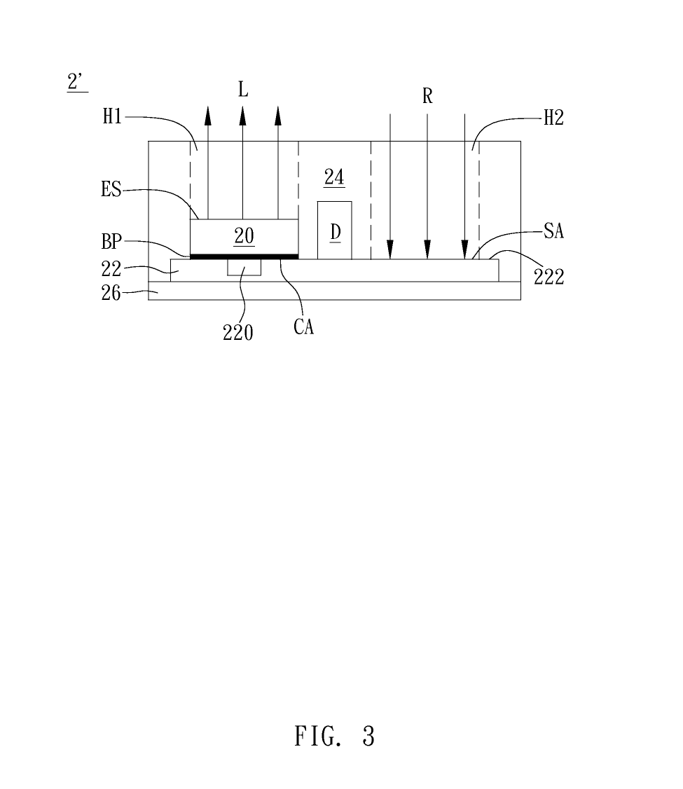

For example, as shown in FIG. 3, the proximity sensor 2′ further includes a barrier portion D. The barrier portion D is disposed on the first surface 222 of the light sensor 22 and between the light emitting unit 20 and the light sensing area SA. In this embodiment, the functions of the barrier portion D includes: (1) preventing the cross-talk generated by scattering the lights L of the light emitting unit 20 to the light sensing area SA on the light sensor 22; and (2) separating the glue encapsulating on the light emitting unit 20 and the glue encapsulating on the light sensing area SA to prevent the misjudgment of the light sensor 22 due to the connection between them.

In practical applications, the barrier portion D can be formed by a die, such as a dummy die or other light-blocking materials, and the height and width of the barrier portion D can be adjusted based on practical needs without specific limitations.

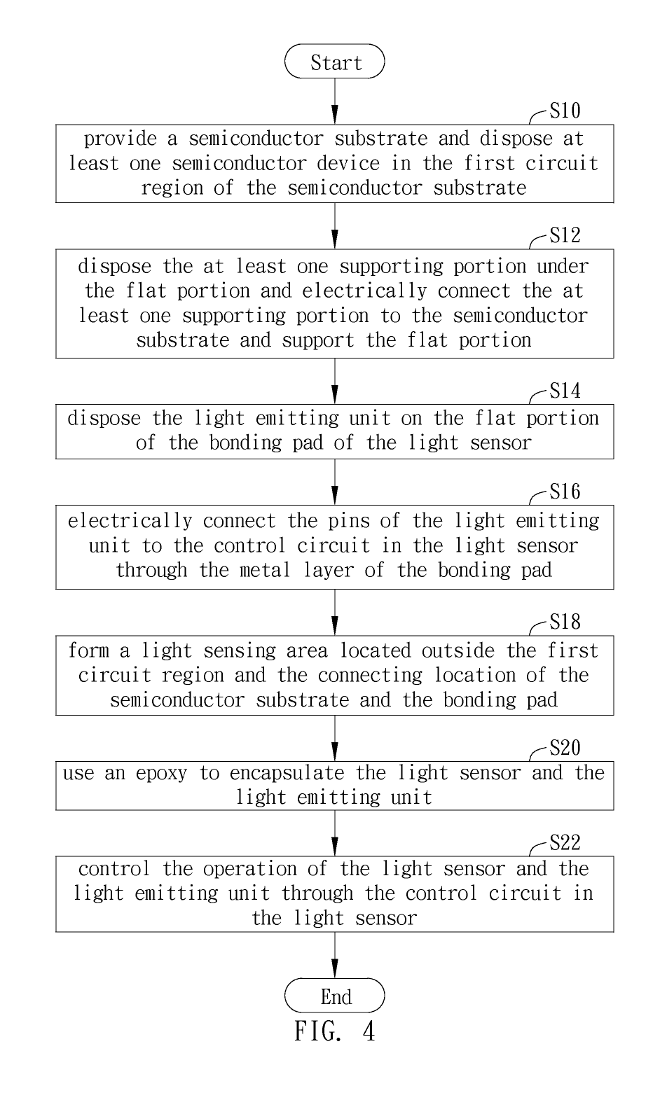

Another preferred embodiment of the invention is a proximity sensor circuit layout method. In this embodiment, the proximity sensor circuit layout method is used to form the circuit layout of the proximity sensor. Please refer to FIG. 4. FIG. 4 illustrates a flowchart of the proximity sensor circuit layout method in this embodiment.

As shown in FIG. 4, in the step S10, the method provides a semiconductor substrate and disposes at least one semiconductor device in the first circuit region of the semiconductor substrate. In fact, the first circuit region of the semiconductor substrate can be a digital circuit region and the second circuit region of the semiconductor substrate can be an analog circuit region, but not limited to this. The bonding pad includes a flat portion and at least one supporting portion. In the step S12, the method disposes the at least one supporting portion under the flat portion and electrically connects the at least one supporting portion to the semiconductor substrate and supports the flat portion, wherein a gap is existed between the bonding pad and the at least one semiconductor device. In fact, the connecting location of the semiconductor substrate and the at least one supporting portion of the bonding pad can be located out of the first circuit region, but not limited to this. In the step S14, the method disposes the light emitting unit on the flat portion of the bonding pad of the light sensor.

In the step S16, the method electrically connects the pins of the light emitting unit to the control circuit in the light sensor through the metal layer of the bonding pad. In the step S18, the method forms a light sensing area located outside the first circuit region and the connecting location of the semiconductor substrate and the bonding pad, wherein the light sensing area and a light emitting surface of the light emitting unit are located on different planes respectively. In the step S20, the method uses an epoxy to encapsulate the light sensor and the light emitting unit. In the step S22, the method controls the operation of the light sensor and the light emitting unit through the control circuit in the light sensor.

In practical applications, the method can dispose the barrier portion on the first surface of the light sensor and between the light emitting unit and the light sensing area. It should be noticed that the aim of disposing the barrier portion between the light emitting unit and the light sensing area is to (1) prevent the cross-talk generated by the lights of the light emitting unit scattered to the light sensing area on the light sensor; and (2) separate the glue encapsulating on the light emitting unit and the glue encapsulating on the light sensing area to prevent the misjudgment of the light sensor due to the connection between them.

Compared to the prior arts, in the proximity sensor and circuit layout method thereof of the invention, the connecting metal layers of the semiconductor devices in the digital (or analog) circuit region of the light sensor are appropriately distributed without the top metal layer disposed at the top. Instead, the bonding pad is disposed above the light sensor to form the gaps between the bonding pad and the semiconductor devices, and the pins of the light emitting unit can be electrically connected to the control circuit in the light sensor through the metal layer of the bonding pad; therefore, the volume of the entire proximity sensor can be effectively reduced. In order to increase the reliability of the light emitting unit connecting to the light sensor, the thickness of the metal layer of the bonding pad can be increased or a layer of Polyimide (PI) is encapsulated as a protection layer.

In addition, the light emitting surface of the light emitting unit and the light sensing area on the light sensor are located on different planes respectively, and the barrier portion is disposed between the light emitting unit and the light sensing area; therefore, the cross-talk generated by scattering the lights of the light emitting unit to the light sensing area on the light sensor can be effectively prevented, so that the proximity sensor will not malfunction due to misjudgment.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A proximity sensor, comprising:
a light sensor, comprising:
a semiconductor substrate, having a first circuit region, at least one semiconductor device being disposed in the first circuit region; and
a bonding pad, disposed above the first circuit region and a gap being existed between the bonding pad and the at least one semiconductor device;
a control circuit; and
a light emitting unit, disposed on the bonding pad, the light emitting unit being electrically connected to the control circuit through the bonding pad.

2. The proximity sensor of claim 1, wherein the bonding pad comprises:
a flat portion, the light emitting unit being disposed on the flat portion; and
at least one supporting portion, disposed under the flat portion, for connecting to a region of the semiconductor substrate outside the first circuit region and supporting the flat portion, wherein the flat portion is located above the first circuit region and the gap is existed between the flat portion and the at least one semiconductor device.

3. The proximity sensor of claim 1, wherein the control circuit is disposed in the light sensor and used to control the operation of the light sensor and the light emitting unit.

4. The proximity sensor of claim 1, wherein the control circuit is disposed in the light sensor, the bonding pad has a metal layer, a pin of the light emitting unit is electrically connected to the control circuit through the metal layer.

5. The proximity sensor of claim 1, wherein the light sensor and the light emitting unit are dies.

6. The proximity sensor of claim 1, further comprising:
an epoxy, for encapsulating the light sensor and the light emitting unit.

7. The proximity sensor of claim 1, wherein the light sensor has a light sensing area, and the light sensing area is located outside the first circuit region and the connecting location of the substrate and the bonding pad.

8. The proximity sensor of claim 1, wherein a light emitting surface of the light emitting unit and a light sensing area on the light sensor are located on different planes respectively.

9. A circuit layout method for a proximity sensor circuit, comprising steps of:
(a) providing a semiconductor substrate and disposing at least one semiconductor device in a first circuit region of the semiconductor substrate;
(b) disposing a bonding pad above the first circuit region and a gap being existed between the bonding pad and the at least one semiconductor device;
(c) providing a control circuit; and
(d) disposing a light emitting unit on the bonding pad, and electrically connecting the light emitting unit to the control circuit through the bonding pad.

10. The circuit layout method of claim 9, wherein the bonding pad comprises a flat portion and at least one supporting portion, the step (b) further comprises steps of:
disposing the at least one supporting portion under the flat portion;
connecting the at least one supporting portion to a region of the semiconductor substrate outside the first circuit region and supporting the flat portion and supporting the flat portion; and
disposing the light emitting unit on the flat portion.

11. The circuit layout method of claim 9, further comprising the step of:
using the control circuit disposed in the light sensor to control the operation of the light sensor and the light emitting unit.

12. The circuit layout method of claim 9, further comprising the step of:
electrically connecting a pin of the light emitting unit to the control circuit disposed in the light sensor through a metal layer of the bonding pad.

13. The circuit layout method of claim 9, further comprising the step of:
using an epoxy to encapsulate the light sensor and the light emitting unit.

14. The circuit layout method of claim 9, further comprising the step of:
forming a light sensing area located outside the first circuit region and the connecting location of the substrate and the bonding pad, wherein the light sensing area and a light emitting surface of the light emitting unit are located on different planes respectively.
